(19) United States
(12) Patent Application Publication
(10) Pub. No.: US 2025/0046582 A1
(43) Pub. Date: Feb. 6, 2025

(54) REGENERATING METHOD FOR INNER MEMBER OF PLASMA PROCESSING APPARATUS

(71) Applicant: Hitachi High-Tech Corporation, Minato-ku, Tokyo (JP)

(72) Inventors: Wenhao WANG, Tokyo (JP); Tadayoshi KAWAGUCHI, Tokyo (JP); Koji NAGAI, Tokyo (JP)

(21) Appl. No.: 18/280,390

(22) PCT Filed: May 23, 2022
(86) PCT No.: PCT/JP2022/021060

§ 371 Date: Sep. 5, 2023

(51) Int. Cl. H01J 37/32; C23C 4/01; C23C 4/04; C23C 4/11; C23C 4/134

(52) U.S. Cl. CPC H01J 37/32807; C23C 4/01; C23C 4/04; C23C 4/11; C23C 4/134

(57) ABSTRACT

An inner wall member 40 provided on the inner wall of a processing chamber, in which plasma processing is performed, includes a base 41, an anodized film 42a, and a sprayed film 42b. The base 41 has a surface FS1, a surface FS2 located at a position higher than the surface FS1, and has a side surface SS1. A method for regenerating the inner wall member 40 includes the steps of (a) covering the anodized film 42a exposed from the sprayed film 42b by a mask material 100, (b) removing, by blasting, the sprayed film 42b on the surface FS2 while leaving the sprayed film 42b on the side surface SS1 and part of the surface FS1, (c) removing the mask material 100, (d) covering the anodized film 42a, which is located at a position away from the remaining sprayed film 42b, by a mask material 101, (e) forming a new sprayed film 42b on the surface FS2, on the side surface SS1, and on part of the surface FS1 by spraying so as to cover the remaining sprayed film 42b, and (f) removing the mask material 101.

### TECHNICAL FIELD

The present invention relates to a method for regenerating an inner wall member, and more particularly to a method for regenerating an inner wall member provided on an inner wall of a processing chamber, in which plasma processing is performed, of a plasma processing apparatus.

### BACKGROUND ART

A wafer including semiconductor is processed to manufacture an electronic device. In this manufacturing process, etching using plasma is used to form a circuit structure on a surface of the wafer. Such processing with plasma etching is required to be improved in processing accuracy and in yield with higher integration of electronic devices.

A plasma processing apparatus used for plasma etching has a processing chamber disposed within a vacuum vessel. A base of an internal member provided in the processing chamber is typically made of a metal such as aluminum or stainless steel from the viewpoint of strength and cost. Since the internal member is exposed to plasma, a coating having high plasma resistance is provided on a surface of the base. This prevents the surface of the base from being worn by the plasma for a longer period of time. Alternatively, this reduces the amount of interaction or a change in properties between the plasma and the surface of the internal member.

An anodized film and a sprayed film are each generally used as the coating with high plasma resistance. However, a thickness of the sprayed film inevitably decreases due to deterioration after prolonged use. A surface of the sprayed film deteriorates after prolonged use, and particles of the sprayed film are thus worn through interaction with plasma, which disadvantageously results in a decrease in the thickness of the sprayed film. If the surface of the base is exposed within the processing chamber, particles of the metal material constituting the base may adhere to the wafer being processed inside the processing chamber, resulting in contamination of the wafer. Hence, a sprayed film is formed again by spraying on the surface of the member having the sprayed film that has been deteriorated, damaged, or worn through prolonged use.

Patent literature 1 discloses a member for an inner wall of a processing chamber with such a coating having plasma resistance. The patent literature 1 discloses an yttrium oxide film as an example of the coating.

Patent literature 2 discloses a technique of re-forming a sprayed film made of the same material when a sprayed film formed on a surface of a base deteriorates after prolonged use.

### CITATION LIST

### Patent Literature

Patent Literature 1: Japanese Unexamined Patent Application Publication No. 2004-100039
Patent Literature 2: Japanese Unexamined Patent Application Publication No. 2007-332462

### SUMMARY OF INVENTION

### Technical Problem

In the background art, various problems have arisen due to insufficient consideration of the following points. In the background art, during spraying, a mask material is provided at a portion where spraying is not desired, and a film is formed on a portion exposed from the mask material. At this time, part of the sprayed film is also formed on the mask material. When the mask material is removed after spraying, since the sprayed film formed on the mask material is separated from the main sprayed film, burrs are easily generated in a portion in contact with the mask material. The burrs are easily removed and become foreign substances, causing contamination of the inside of the processing chamber.

Moreover, if the anodized film covered with the sprayed film is also removed during removal of the deteriorated sprayed film, an end of the anodized film may gradually recede with an increase in number of times of regeneration of the sprayed film. On the other hand, if the sprayed film is removed so as to leave the sprayed film overlapping the anodized film, the remaining sprayed film piles up at every respraying. The remaining sprayed film that has piled up is likely to peel off and become a cause of a foreign substance.

A main object of the present application is to provide a method for regenerating an internal member so as to suppress generation of a foreign substance in a plasma processing apparatus. Other problems and novel features will be clarified from the content of this description and the accompanying drawings.

### Solution to Problem

Among embodiments disclosed in the present application, a typical one of summary is briefly described as follows.

A method for regenerating an inner wall member according to one embodiment is a method for regenerating an inner wall member provided on an inner wall of a processing chamber, in which plasma processing is performed, of a plasma processing apparatus. The inner wall member includes: a base having a first surface, a second surface located at a position higher than the first surface, and a first side surface connecting the first surface and the second surface; an anodized film formed on the first surface and the first side surface; and a first sprayed film formed on the second surface, on the first side surface, and on part of the first surface so as to cover the anodized film on the first side surface and cover part of the anodized film on the first surface. Further, the method for regenerating an inner wall member comprises: (a) covering the anodized film exposed from the first sprayed film by a first mask material; (b) after the step (a), removing, by blasting, the first sprayed film on the second surface while leaving the first sprayed film on the first side surface and on part of the first surface; (c) after the step (b), removing the first mask material; (d) after the step (c), covering the anodized film located at a position away from the remaining first sprayed film by a second mask material; (e) after the step (d), forming by spraying a second sprayed film including the same material as the first sprayed film on the second surface, on the first side surface, and on part of the first surface so as to cover the remaining first sprayed film; and (f) after the step (e), removing the second mask material.

The method for regenerating an inner wall member according to one embodiment is a method for regenerating an inner wall member provided on an inner wall of a processing chamber, in which plasma processing is performed, of a plasma processing apparatus. The inner wall member includes: a base having a first surface, a second surface located at a position higher than the first surface, a first side surface connecting the first surface and the second surface, a third surface located at a position higher than the first surface but lower than the second surface, and a second side surface connecting the first surface and the third surface; an anodized film formed on the third surface, on the second side surface, on the first surface, and on the first side surface; and a first sprayed film formed on the second surface, on the first side surface, and on part of the first surface so as to cover the anodized film formed on the first side surface and part of the anodized film formed on the first surface. Further, the method for regenerating an inner wall member comprises: (a) covering the anodized film exposed from the first sprayed film by a first mask material; (b) after the step (a), removing the first sprayed film on the second surface while leaving the first sprayed film on the first side surface and part of the first surface by projecting blasting particles from a direction from the second surface toward the first surface and inclined at a predetermined angle with respect to the first surface; (c) after the step (b), removing the first mask material; (d) after the step (c), covering the anodized film on the third surface by a second mask material; (e) after the step (d), forming a second sprayed film on the second surface, on the first side surface, and on part of the first surface so as to cover the remaining first sprayed film by projecting particles including the same material as the first sprayed film from a direction from the third surface toward the first surface and inclined at a predetermined angle with respect to the first surface; and (f) after the step (e), removing the second mask material.

### Advantageous Effects of Invention

According to one embodiment, it is possible to provide a method for regenerating an internal member so as to suppress generation of a foreign substance in a plasma processing apparatus.

### BRIEF DESCRIPTION OF DRAWINGS

FIG. 1 is a schematic diagram illustrating a plasma processing apparatus in a first embodiment.

FIG. 2 is a conceptual diagram illustrating an inner wall member in the first embodiment.

FIG. 3 is a plan diagram illustrating the inner wall member in the first embodiment.

FIG. 4 is a cross-sectional diagram illustrating the inner wall member in the first embodiment.

FIG. 5A is a cross-sectional diagram illustrating a base of the inner wall member in the first embodiment.

FIG. 5B is a cross-sectional diagram illustrating a method for manufacturing the inner wall member in the first embodiment.

FIG. 5C is a cross-sectional diagram illustrating the method for manufacturing the inner wall member following FIG. 5B.

FIG. 5D is a cross-sectional diagram illustrating a method for regenerating the inner wall member in the first embodiment.

FIG. 5E is a cross-sectional diagram illustrating the method for regenerating the inner wall member following FIG. 5D.

FIG. 5F is a cross-sectional diagram illustrating the method for regenerating the inner wall member following FIG. 5E.

FIG. 5G is a cross-sectional diagram illustrating the method for regenerating the inner wall member following FIG. 5F.

### DESCRIPTION OF EMBODIMENTS

Hereinafter, one embodiment will be described in detail with reference to drawings. In all drawings for explaining the embodiment, components having the same function are designated by the same sign, and duplicated description is omitted. In the following embodiment, the same or similar portion is not repeatedly described in principle except for a particularly required case.

The X, Y, and Z directions described herein intersect each other and are orthogonal to each other. The expression such as “plan diagram” or “plan view” used herein means viewing a plane, which is configured by the X direction and the Y direction, from the Z-direction.

### First Embodiment

### Configuration of Plasma Processing Apparatus

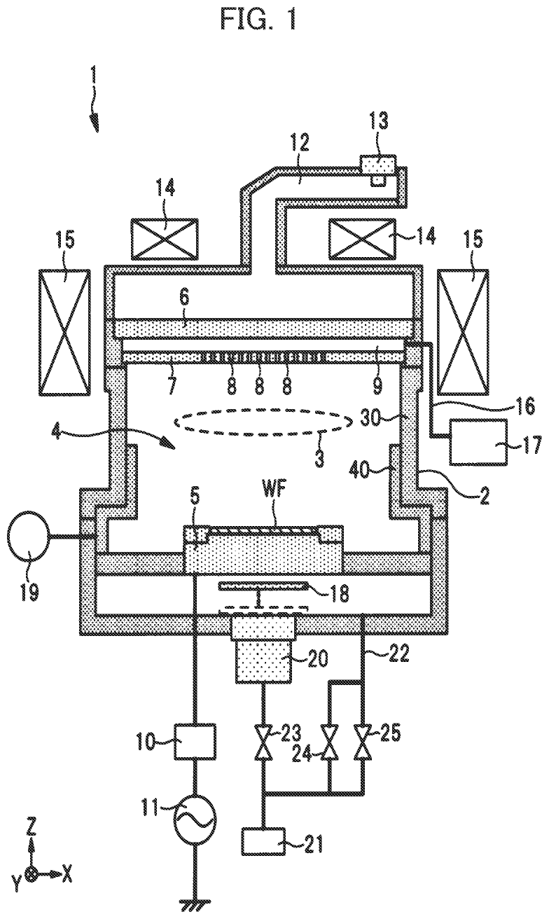

An outline of a plasma processing apparatus 1 in a first embodiment is now described with reference to FIG. 1.

The plasma processing apparatus 1 includes a cylindrical vacuum vessel 2, a processing chamber 4 provided inside the vacuum vessel 2, and a stage 5 provided inside the processing chamber 4. The upper part of the processing chamber 4 forms a discharge chamber as a space where plasma 3 is generated.

A disk-shaped window member 6 and a disk-shaped plate 7 are provided above the stage 5. The window member 6 is made of a dielectric material such as quartz or ceramics, and hermetically seals the inside of the processing chamber 4. The plate 7 is provided below the window member 6 so as to be spaced apart from the window member 6, and is made of a dielectric material, for example, quartz. The plate 7 has a plurality of through holes 8. A gap 9 is provided between the window member 6 and the plate 7, and a processing gas is supplied into the gap 9 during plasma processing.

The stage 5 is used to place thereon a wafer WF as a material to be processed when plasma processing is performed on the wafer WF. The wafer WF is, for example, a substrate made of a semiconductor material such as silicon, or a stacked structure including a semiconductor element, an insulating film, and a conductive film formed on the substrate. The stage 5 is a member, the vertical central axis of which is disposed at a position concentric or approximately concentric with the discharge chamber of the processing chamber 4 when viewed from above, and has a cylindrical shape.

The space between the stage 5 and the bottom of the processing chamber 4 communicates with the space above the stage 5 through the gap between the side wall of the stage 5 and the side surface of the processing chamber 4. As a result, a product generated during processing of the wafer WF placed on the stage 5, and particles of the plasma 3 or gas are discharged to the outside of the processing chamber 4 through the space between the stage 5 and the bottom of the processing chamber 4.

While not shown in detail, the stage 5 has a base having a cylindrical shape and made of a metal material. The upper surface of the base is covered with a dielectric film. The dielectric film has therein a heater and a plurality of electrodes above the heater. A DC voltage is supplied to the electrodes. The DC voltage can generate electrostatic force within the dielectric film and the wafer WF so that the wafer WF is adsorbed to the upper surface of the dielectric film and held. The plurality of electrodes are arranged point-symmetrically around the vertical central axis of the stage 5, and voltages with polarities different from each other are applied to the electrodes.

The stage 5 has a refrigerant channel that is multiply arranged in a concentric or helical shape. While the wafer WF is placed on the upper surface of the dielectric film, a heat-conductive gas such as helium (He) is supplied into a gap between the lower surface of the wafer WF and the upper surface of the dielectric film. Pipes, through which the gas flows, are therefore respectively disposed within the base and the dielectric film.

The plasma processing apparatus 1 further includes an impedance matching box 10 and a high-frequency power supply 11. The high-frequency power supply 11 is connected to the base of the stage 5 via the impedance matching box 10. During plasma processing of the wafer WF, high-frequency power is supplied from the high-frequency power supply 11 to the base, in order to form an electric field for attracting charged particles in the plasma onto the upper surface of the wafer WF.

The plasma processing apparatus 1 further includes a waveguide 12, a magnetron generator 13, a solenoid coil 14, and a solenoid coil 15. The waveguide 12 is provided above the window member 6, and the magnetron generator 13 is provided at one end of the waveguide 12. The magnetron generator 13 can oscillate and output an electric field of a microwave. The waveguide 12 is a conduit through which the electric field of the microwave propagates, and the electric field of the microwave is supplied to the inside of the processing chamber 4 through the waveguide 12. The solenoid coil 14 and the solenoid coil 15 are provided around the waveguide 12 and the processing chamber 4, respectively, and are each used as a magnetic field generating unit.

The waveguide 12 includes a rectangular waveguide portion and a circular waveguide portion. The rectangular waveguide portion has a rectangular cross-sectional shape and extends in the horizontal direction. The magnetron generator 13 is provided at one end of the rectangular waveguide portion. The circular waveguide portion is connected to the other end of the rectangular waveguide portion. The circular waveguide portion has a circular cross-sectional shape and is configured such that the central axis extends in the vertical direction.

The plasma processing apparatus 1 further includes a pipe 16 and a gas supply device 17. The gas supply device 17 is connected to the processing chamber 4 through the pipe 16. The processing gas is supplied into the gap 9 from the gas supply device 17 through the pipe 16 and diffuses within the gap 9. The processing gas that has diffused is supplied above the stage 5 through the through holes 8.

The plasma processing apparatus 1 further includes a pressure adjusting plate 18, a pressure detector 19, a turbomolecular pump 20 being a high vacuum pump, a dry pump 21 being a roughing pump, an exhaust pipe 22, and valves 23 to 25. A space between the stage 5 and the bottom of the processing chamber 4 serves as a vacuum evacuation part. The pressure adjusting plate 18 is a disk-shaped valve that moves up and down above an exhaust port to increase or decrease area of a channel through which gas flows into the exhaust port. That is, the pressure adjusting plate 18 also serves as a valve for opening and closing the exhaust port.

The pressure detector 19 is a sensor for detecting internal pressure of the processing chamber 4. A signal output from the pressure detector 19 is transmitted to a control unit (not shown) that then detects a pressure value and outputs a command signal according to the detected value. Based on the command signal, the pressure adjusting plate 18 is driven so that a vertical position of the pressure adjusting plate 18 changes to increase or decrease the area of the exhaust channel.

The outlet of the turbomolecular pump 20 is connected to the dry pump 21 through a pipe, and a valve 23 is provided in the middle of the pipe. The space between the stage 5 and the bottom of the processing chamber 4 is connected to the exhaust pipe 22 having a valve 24 and a valve 25. The valve 24 is a slow exhaust valve to slowly evacuate the processing chamber 4 from the atmospheric pressure to a vacuum state by the dry pump 21, and the valve 23 is a main exhaust valve to evacuate the processing chamber 4 at a high speed by the turbomolecular pump 20.

### Plasma Processing

A case of performing etching processing using the plasma 3 on a certain film, which is formed in advance on the upper surface of the wafer WF, is now described as an example of plasma processing.

The wafer WF is placed on the tip of an arm of a vacuum transfer system, such as a robotic arm, from the outside of the plasma processing apparatus 1, transported to the inside of the processing chamber 4, and placed on the stage 5. When the arm of the vacuum transfer system exits the processing chamber 4, the inside of the processing chamber 4 is sealed. A DC voltage is then applied to the electrodes for electrostatic adsorption inside the dielectric film of the stage 5 to generate electrostatic force by which the wafer WF is held on the dielectric film.

In this state, the heat-conductive gas such as helium (He) is supplied into the gap between the wafer WF and the dielectric film through the pipe that is provided inside the stage 5. A refrigerant adjusted to a predetermined temperature by a refrigerant temperature adjustor (not shown) is supplied to the refrigerant channel inside the stage 5. This promotes heat transfer between the base having the adjusted temperature and the wafer WF, so that temperature of the wafer WF is adjusted to a value within a range suitable for start of the plasma processing.

The processing gas, of which the flow rate and the speed are adjusted by the gas supply device 17, is supplied to the inside of the processing chamber 4 through the pipe 16, and the processing chamber 4 is evacuated through the exhaust port by operation of the turbomolecular pump 20. By balancing such supply and exhaust of the gas, internal pressure of the processing chamber 4 is adjusted to a value within a range suitable for plasma processing.

In this state, the magnetron generator 13 generates a microwave electric field. The microwave electric field propagates within the waveguide 12 and passes through the window member 6 and the plate 7. Furthermore, the magnetic field generated by the solenoid coil 14 and the solenoid coil 15 is applied to the processing chamber 4. Electron cyclotron resonance (ECR) is caused by an interaction between the magnetic field and the microwave electric field. The plasma 3 is generated inside the processing chamber 4 by excitation, ionization, or dissociation of the atoms or molecules of the processing gas.

When the plasma 3 is generated, high-frequency power is supplied from the high-frequency power supply 11 to the base of the stage 5, a bias potential is formed on the upper surface of the wafer WF, and charged particles such as ions in the plasma 3 are attracted to the upper surface of the wafer WF. As a result, etching processing is performed on the predetermined film of the wafer WF so as to trace a pattern shape of a mask layer. Subsequently, when it is detected that the processing of the film to be processed has reached its end point, the high-frequency power supply 11 stops supply of the high frequency power to stop the plasma processing.

If there is no need for further etching processing of the wafer WF, high vacuum evacuation is performed. After the static electricity is removed and adsorption of the wafer WF is released, the arm of the vacuum transfer system enters the processing chamber 4 and the processed wafer WF is transferred to the outside of the plasma processing apparatus 1.

### Inner Wall Member of Processing Chamber

As illustrated in FIG. 1, an inner wall member 40 is provided on the inner wall of the processing chamber 4, in which plasma processing is performed, of the plasma processing apparatus 1. The inner wall member 40 serves, for example, as a ground electrode to stabilize potential of the plasma 3 being a dielectric.

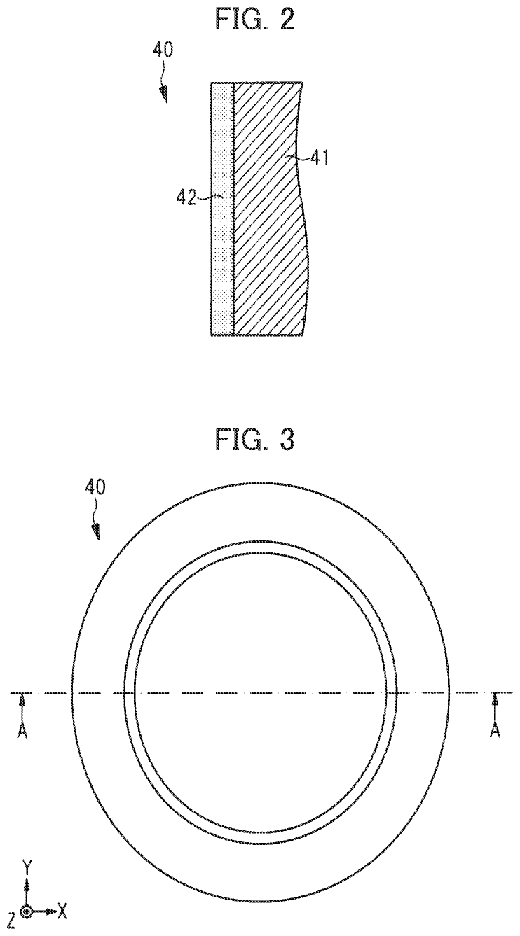

As illustrated in FIG. 2, the inner wall member 40 includes a base 41 and a coating 42 covering the surface of the base 41. The base 41 is made of a conductive material such as a metal material, for example, aluminum, aluminum alloy, stainless steel, or stainless steel alloy.

The inner wall member 40 is exposed to the plasma 3 during plasma processing. If the coating 42 does not exist on the surface of the base 41, the base 41 is directly exposed to the plasma 3 and thus may be corroded or may become a source of a foreign substance, leading to contamination of the wafer WF. The coating 42, which is provided to suppress contamination of the wafer WF, includes a material having higher resistance to the plasma 3 than the base 41. The coating 42 can maintain the function of the inner wall member 40 as the ground electrode and can protect the base 41 from the plasma 3.

A metal material such as stainless alloy or aluminum alloy is also used for a base 30 that does not serve as a ground electrode. The surface of the base 30 is therefore also subjected to processing for improving resistance to the plasma 3 or processing for reducing wear of the base 30, in order to suppress corrosion or generation of a foreign substance caused by exposure to the plasma 3. Examples of such processing include passivation, formation of a sprayed film, or film formation by a PVD or CVD process.

Although not shown, a cylindrical cover made of ceramic such as yttrium oxide or quartz may be disposed inside the inner wall of the cylindrical base 30 in order to reduce wear of the base 30 by the plasma 3. Placing such a cover between the base 30 and the plasma 3 blocks or reduces contact between the base 30 and highly reactive particles in the plasma 3 or collision between the base 30 and charged particles. This can suppress wear of the base 30.

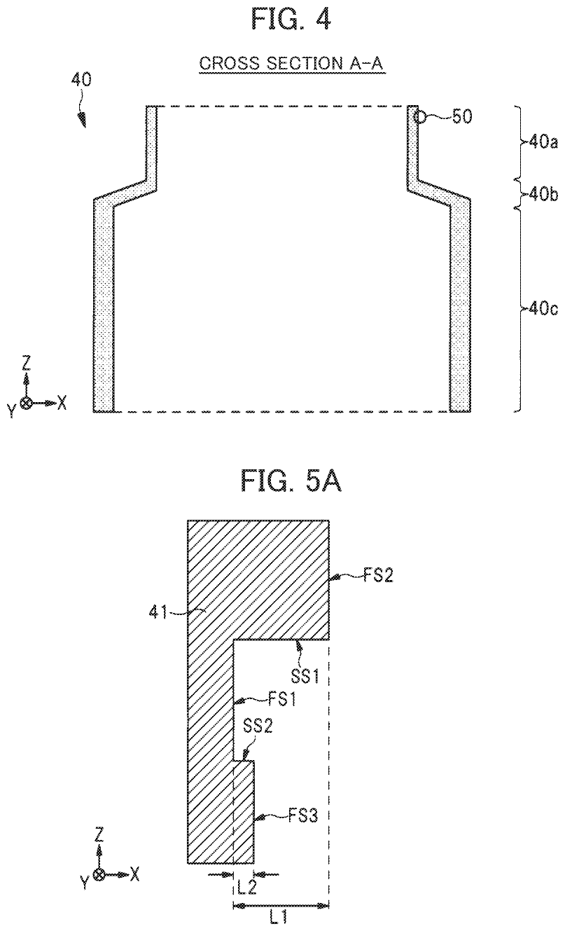

A configuration of the inner wall member 40 is now described with reference to FIGS. 3 and 4. FIG. 3 is a plan diagram illustrating the inner wall member 40, and FIG. 4 is a cross-sectional diagram taken along the line A-A in FIG. 3.

The inner wall member 40 (base 41) generally has a cylindrical shape having a predetermined thickness between the inner circumference and the outer circumference. The inner wall member 40 includes an upper part 40a, a middle part 40b, and a lower part 40c. The upper part 40a is a portion where inner and outer diameters of the cylinder are each relatively small, and the lower part 40c is a portion where inner and outer diameters thereof are each relatively large. The middle part 40b is a portion for connecting the upper part 40a and the lower part 40c, and has, for example, a truncated cone shape in which each of the inner and outer diameters of the cylinder changes continuously.

The inner wall member 40 is provided along the inner wall of the processing chamber 4 so as to surround the outer circumference of the stage 5. A sprayed film is formed by spraying as part of the coating 42 on the surface on the inner circumferential side of the inner wall member 40 (surface on the inner circumferential side of the base 41). While the inner wall member 40 is attached inside the processing chamber 4, an anodized film is formed by anodizing as part of the coating 42 on the surface on the outer circumferential side of the inner wall member 40 (surface on the outer circumferential side of the base 41).

The sprayed film is formed not only on the surface on the inner circumferential side of the base 41 but also on the surface on the outer circumferential side thereof via the upper end portion of the upper part 40a. The reason for this is that particles in the plasma 3 may flow from the inner circumferential side to the outer circumferential side of the inner wall member 40 at the upper part 40a and may interact with the surface on the outer circumferential side of the base 41. It is therefore necessary to form the sprayed film on the surface on the outer circumferential side of the base 41 up to a region into which the particles in the plasma 3 are expected to flow. FIG. 4 shows such a region as region 50.

### Structure and Manufacturing Method of Inner Wall Member in First Embodiment

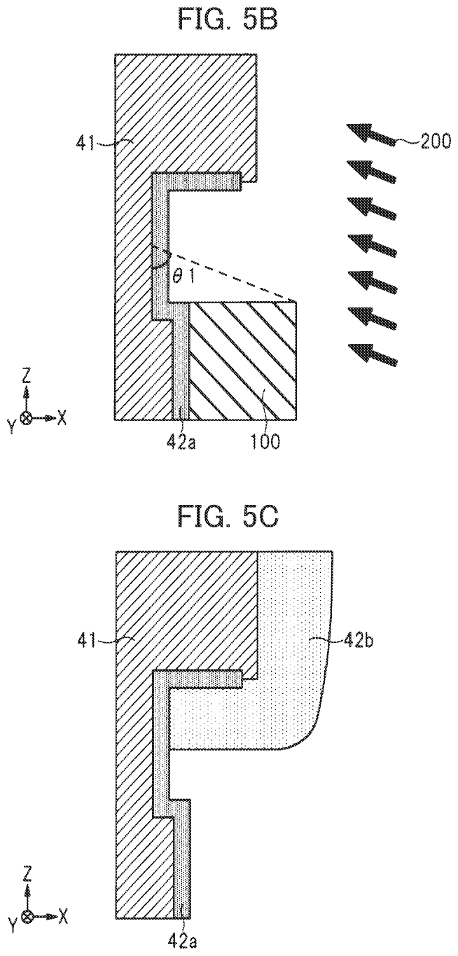

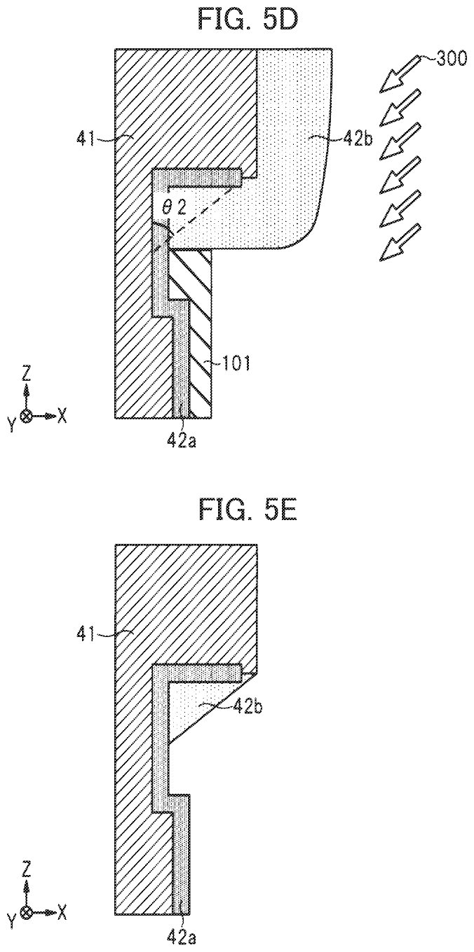

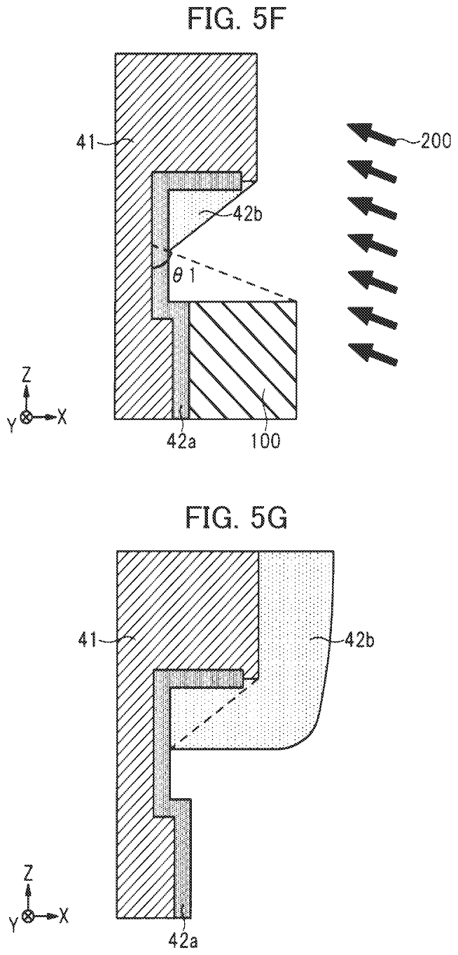

FIGS. 5A to 5G are enlarged cross-sectional diagrams of the region 50 shown in an enlarged manner. A structure and a manufacturing method of the inner wall member 40 are now described with reference to FIGS. 5A to 5C. The inner wall member 40 in the first embodiment includes the base 41, an anodized film 42a, and a sprayed film 42b as described below. The anodized film 42a and the sprayed film 42b each configure part of the coating 42.

FIG. 5A shows the base 41 before the anodized film 42a and the sprayed film 42b are formed. As shown in FIG. 5A, the base 41 in the first embodiment has two steps in the X direction, i.e., in a direction from the inner circumferential side of the inner wall member 40 (inner circumferential side of the base 41) to the outer circumferential side thereof (outer circumferential side of the base 41).

Specifically, the base 41 has a surface FS1, a surface FS2, a side surface SS1, a surface FS3, and a side surface SS2 on the outer circumferential side of the base 41. The surface FS2 is located at a higher position than the surface FS1. The side surface SS1 connects the surface FS1 and the surface FS2 to each other. The surface FS3 is located at a position higher than the surface FS1 but lower than the surface FS2. The side surface SS2 connects the surface FS1 and the surface FS3 to each other.

A distance L1 between the surface FS1 and the surface FS2 corresponds to height of one step, for example, 0.6 mm. A distance L2 between the surface FS1 and the surface FS3 corresponds to height of the other step, for example, 0.1 mm.

As shown in FIG. 5B, the anodized film 42a is formed by anodizing before the sprayed film 42b is formed. The anodized film 42a is formed on the surface FS3, on the side surface SS1, on the surface FS1, and on the side surface SS2. When the base 41 includes, for example, aluminum or aluminum alloy, the anodized film 42a is an alumite film.

Subsequently, the anodized film 42a on the surface FS3 is covered by a mask material 100. The mask material 100 is a jig, for example. In this state, the sprayed film 42b is formed by spraying. In the spraying, plasma is generated under atmospheric pressure, and particles of yttrium oxide, yttrium fluoride, or a material containing such particles are supplied into the plasma so that the particles are made into a semi-molten state. The surface FS1 and the surface FS2 are irradiated with the semi-molten particles 200. At this time, the particles 200 are projected from a direction from the surface FS3 toward the surface FS1 and inclined at a predetermined angle θ1 with respect to the surface FS1.

As shown in FIG. 5C, the sprayed film 42b is formed by the spraying on the surface FS2, on the side surface SS1, and on part of the surface FS1. Further, the sprayed film 42b is formed so as to cover the anodized film 42a on the side surface SS1 and part of the anodized film 42a on the surface FS1. Since the particles 200 are projected from the direction inclined at the angle θ1, the surface FS1 near the mask material 100 is not irradiated with the particles 200, and the sprayed film 42b is formed at a position away from the mask material 100. That is, the sprayed film 42b is formed at a position away from the surface FS3 and the side surface SS2.

After that, the mask material 100 is removed. At this time, the mask material 100 is not in contact with the sprayed film 42b. It is therefore possible to solve the problem of the background art, that is, contamination of the inside of the processing chamber 4 due to generation of burrs that then become foreign substances.

Unevenness of the surface of the sprayed film 42b is designed such that arithmetic mean roughness (surface roughness) Ra of the surface is 8 or less, for example. The average size of the particles (average particle diameter) of the sprayed film 42b is, for example, 10 μm or more and 50 μm or less in volume-based D50.

In the region 50, the surface FS1, the surface FS2, the surface FS3, the side surface SS1, and the side surface SS2 are covered with the anodized film 42a and/or the sprayed film 42b, which prevents the base 41 from being exposed to the plasma 3 during plasma processing.

### Regenerating Method for Inner Wall Member According to First Embodiment

A method for regenerating the inner wall member 40 is now described with reference to FIGS. 5D to 5G. The method for regenerating the inner wall member 40 can also be said to be the method for manufacturing the inner wall member 40 following FIG. 5C.

The inner wall member 40 of FIG. 5C is placed within the processing chamber 4 and exposed to the plasma 3 during a predetermined period of time. Since the sprayed film 42b exposed to the plasma 3 is modified or worn, it is necessary to remove the sprayed film 42b and regenerate the sprayed film 42b.

First, as shown in FIG. 5D, the anodized film 42a exposed from the sprayed film 42b is covered by a mask material 101. The mask material 101 includes a material that is characteristically not removed by blasting described later, and is, for example, a jig or a resin tape.

Subsequently, blasting is performed on the sprayed film 42b. The blasting is performed by projecting blasting particles 300 from a direction from the surface FS2 toward the surface FS1 and inclined at a predetermined angle θ2 with respect to the surface FS1. The blasting particles 300 collide with particles of the sprayed film 42b, so that the sprayed film 42b is removed due to a physical action.

As shown in FIG. 5E, the blasting removes the sprayed film 42b on the surface FS2 while leaving the sprayed film 42b on the side surface SS1 and part of the surface FS1. The projection angle θ2 of the blasting particles 300 can be appropriately selected to leave part of the sprayed film 42b. Subsequently, the mask material 101 is removed.

Subsequently, as shown in FIG. 5F, the anodized film 42a on the surface FS3 is covered by a mask material 100. Specifically, the mask material 100 covers the anodized film 42a located at a position away from the remaining sprayed film 42b. Subsequently, a new sprayed film 42b is formed by projecting semi-molten particles 200 by spraying. The method and conditions for forming the new sprayed film 42b are the same as those described with reference to FIG. 5B.

Specifically, particles of the same material as the remaining sprayed film 42b are projected from the direction from the surface FS3 toward the surface FS1 and inclined at the predetermined angle θ1 with respect to the surface FS1. As a result, as shown in FIG. 5G, a new sprayed film 42b is formed on the surface FS2, on the side surface SS1, and on part of the surface FS1 so as to cover the remaining sprayed film 42b. Subsequently, the mask material 100 is removed.

In FIG. 5G, when the mask material 100 is removed, the mask material 100 is not in contact with the sprayed film 42b. It is therefore possible to solve the problem of the background art, that is, contamination of the inside of the processing chamber 4 due to generation of burrs that then become foreign substances.

If an extremely large amount of new spray film 42b is formed, the upper part of the spray film 42b may come into contact with the upper part of the mask material 100, leading to generation of burrs during removal of the mask material 100. It is therefore preferable to stop projection of the particles 200 before the spray film 42b comes into contact with the mask material 100.

Since the sprayed film 42b can be regenerated in this manner, the inner wall member 40 is restored to the state of FIG. 5C. In addition, the newly formed sprayed film 42b is made of the same material as the initially formed sprayed film 42b. The sprayed film 42b remaining after the blasting is not directly exposed to the plasma 3 during plasma processing, and is thus substantially not modified. The remaining sprayed film 42b and the new sprayed film 42b are therefore integrated as one sprayed film 42b with high quality.

Subsequently, when the inner wall member 40 is exposed to the plasma 3 again and when the sprayed film 42b is thus modified, the steps of FIGS. 5D to 5G can be repeated to regenerate the sprayed film 42b and regenerate the inner wall member 40.

Although the invention has been specifically described according to the one embodiment hereinbefore, the invention should not be limited thereto, and various modifications can be made within the scope without departing from the gist of the invention.

### LIST OF REFERENCE SIGNS

1: Plasma processing apparatus
2: Vacuum vessel
3: Plasma
4: Processing chamber
5: Stage
6: Window member
7: Plate
8: Through hole
9: Gap
10: Impedance matching box
11: High-frequency power supply
12: Waveguide
13: Magnetron generator
14: Solenoid coil
15: Solenoid coil
16: Pipe
17: Gas supply device
18: Pressure adjusting plate
19: Pressure detector
20: Turbomolecular pump
21: Dry pump
22: Exhaust pipe
23 to 25: Valve
30: Base
40: Inner wall member
40a: Upper part
40b: Middle part
40c: Lower part
41: Base
42: Coating
42a: Anodized film
42b: Sprayed film
50: Region
100, 101: Mask material
200: Semi-molten particles
300: Blasting particles
FS1 to FS3: Surface
SS1, SSC: Side surface
WF: Wafer (material to be processed)

1. A method for regenerating an inner wall member provided on an inner wall of a processing chamber of a plasma processing apparatus, the processing chamber being a chamber in which plasma processing is performed,
the inner wall member including:
a base having a first surface, a second surface located at a position higher than the first surface, and a first side surface connecting the first surface and the second surface;
an anodized film formed on the first surface and the first side surface; and
a first sprayed film formed on the second surface, on the first side surface, and on part of the first surface so as to cover the anodized film on the first side surface and cover part of the anodized film on the first surface,
the method comprising the steps of:
(a) covering the anodized film exposed from the first sprayed film by a first mask material;
(b) after the step (a), removing, by blasting, the first sprayed film on the second surface while leaving the first sprayed film on the first side surface and on part of the first surface;
(c) after the step (b), removing the first mask material;
(d) after the step (c), covering the anodized film located at a position away from the remaining first sprayed film by a second mask material,
(e) after the step (d), forming by spraying a second sprayed film including the same material as the first sprayed film on the second surface, on the first side surface, and on part of the first surface so as to cover the remaining first sprayed film; and
(f) after the step (e), removing the second mask material.

2. The method according to claim 1, wherein
the base has a third surface located at a position higher than the first surface but lower than the second surface, and a second side surface connecting the first surface and the third surface,
the anodized film is also formed on the third surface and on the second side surface, and
in the step (d), the anodized film on the third surface is covered by the second mask material.

3. The method according to claim 2, wherein
in the step (e), the second sprayed film is formed by projecting particles including the same material as the first sprayed film from a direction from the third surface toward the first surface and inclined at a predetermined angle with respect to the first surface.

4. The method according to claim 3, wherein
in the step (e), projection of the particles is stopped before the second sprayed film comes into contact with the second mask material.

5. The method according to claim 1, wherein
in the step (b), the blasting is performed by projecting blasting particles from a direction from the second surface toward the first surface and inclined at a predetermined angle with respect to the first surface.

6. The method according to claim 1, wherein
the base has a cylindrical shape with a predetermined thickness between inner circumference and outer circumference of the cylindrical shape, and
the first surface, the second surface, and the first side surface are provided on the outer circumferential side of the base.

7. A method for regenerating an inner wall member provided on an inner wall of a processing chamber of a plasma processing apparatus, the processing chamber being a chamber in which plasma processing is performed,
the inner wall member including
a base having a first surface, a second surface located at a position higher than the first surface, a first side surface connecting the first surface and the second surface, a third surface located at a position higher than the first surface but lower than the second surface, and a second side surface connecting the first surface and the third surface,
an anodized film formed on the third surface, on the second side surface, on the first surface, and on the first side surface, and
a first sprayed film formed on the second surface, on the first side surface, and on part of the first surface so as to cover the anodized film formed on the first side surface and part of the anodized film formed on the first surface,
the method comprising the steps of:
(a) covering the anodized film exposed from the first sprayed film by a first mask material;
(b) after the step (a), removing the first sprayed film on the second surface while leaving the first sprayed film on the first side surface and part of the first surface by projecting blasting particles from a direction from the second surface toward the first surface and inclined at a predetermined angle with respect to the first surface;
(c) after the step (b), removing the first mask material;
(d) after the step (c), covering the anodized film on the third surface by a second mask material;
(e) after the step (d), forming a second sprayed film on the second surface, on the first side surface, and on part of the first surface so as to cover the remaining first sprayed film by projecting particles including the same material as the first sprayed film from a direction from the third surface toward the first surface and inclined at a predetermined angle with respect to the first surface; and
(f) after the step (e), removing the second mask material.

8. The method according to claim 7, wherein
in the step (e), projection of the particles is stopped before the second sprayed film comes into contact with the second mask material.

9. The method according to claim 7, wherein
the base has a cylindrical shape with a predetermined thickness between inner circumference and outer circumference of the cylindrical shape, and
the first surface, the second surface, the third surface, the first side surface, and the second side surface are provided on the outer circumferential side of the base.
